(19) United States
(12) Patent Application Publication
(10) Pub. No.: US 2013/0000960 A1
(43) Pub. Date: Jan. 3, 2013

(54) PRINTED CIRCUIT BOARD AND METHOD FOR MANUFACTURING THE SAME

(75) Inventors: Dong Jun LEE, Gyeonggi-do (KR); Dong Ju Jeon, Seoul (KR); Jung Youn Pang, Gyeonggi-do (KR); Seong Min Cho, Gyeonggi-do (KR); Chi Seong Kim, Gyeonggi-do (KR)

(73) Assignee: SAMSUNG Electro-Mechanics Co., Ltd.

(21) Appl. No.: 13/472,299

(22) Filed: May 15, 2012

(30) Foreign Application Priority Data
Jun. 28, 2011 (KR) 10-2011-0062944

(51) Int. Cl. H05K 1/09; H05K 3/00

(52) U.S. Cl. 174/257; 427/98.8

(57) ABSTRACT

Disclosed herein are a printed circuit board and a method for manufacturing the same. The printed circuit board includes: a copper pad surface roughness-treated to have a surface roughness of 0.1 to 1.0 μm pitch period; and an electroless surface treatment plating layer formed on the copper pad. According to the present invention, when the copper pad has a surface roughness of a predetermined pitch period, the electroless surface treatment plating layer formed on the copper pad also has a surface roughness of the predetermined pitch period, thereby having an effect of widening a surface area and improving workability at the time of a wire bonding process for connection with an external device.

### CROSS REFERENCE(S) TO RELATED APPLICATIONS

This application claims the benefit under 35 U.S.C. Section 119 of Korean Patent Application Serial No. 10-2011-0062944, entitled “Printed Circuit Board and Method for Manufacturing the Same” filed on Jun. 28, 2011, which is hereby incorporated by reference in its entirety into this application.

### BACKGROUND OF THE INVENTION

1. Technical Field

The present invention relates to a printed circuit board and a method for manufacturing the same.

2. Description of the Related Art

The number of electric input and output terminals is increasing in a PCB product, of which a thickness becomes decreased and a density becomes increased, and corresponding to this trend, a terminal pitch is also decreasing. Recently, the number of wire bonding electric terminals is continuously increasing, and an area of the terminal is gradually decreasing. In addition, a diameter of a wire is decreasing, and due to this change, the number of defects in wire bonding is increasing and workability is being deteriorated.

FIGS. 1A and 1B are a cross-sectional view and a plan view of a printed circuit board at the time of connection with a device by using a wire bonding type, respectively, according to the related art.

Referring to FIGS. 1A and 1B, a polymer resin layer 20 is formed at a region of a printed circuit board except for a copper layer 10. The polymer resin layer 20 functions as a resist against later plating. Then, a Ni layer 31/a Pd layer/an Au layer 33 are formed as a plating layer 30 for protecting the copper layer 10. After the plating layer 30 of Ni/Pd/Au is formed, interconnections between metals are formed by using Au wires.

In the plating layer 30 of Ni/Pd/Au, the thickness of the Ni layer 31 is at least 3 μm, which is thicker than high-priced metal plating layers, that is, the Pd layer 32 or the Au layer 33. Therefore, these layers are likely to follow surface roughness of the Ni layer 31.

Meanwhile, there are an electrolytic plating type and an electroless plating type for forming this Ni layer, and plating shapes obtained from the respective types are slightly different from each other.

For example, FIGS. 2A to 2C are scanning electron microscope images each showing surface roughness observed during each of the procedures for forming a Ni plating layer by using the electrolytic plating type. FIGS. 2A, 2B, and 2C are surface images before forming a plating layer, after soft etching, and after forming an electrolytic Ni/Au surface treatment plate layer, respectively. As shown in respective surface images, it can be seen that flat interfaces having slightly different surface shapes from each other but similar levels of surface roughnesses can be obtained.

Also, FIGS. 3A to 3C are scanning electron microscope images each showing surface roughness observed during each of the procedures for forming a Ni plating layer by using the electroless plating type. FIGS. 3A, 3B, and 3C are surface images before forming a plating layer, after soft etching, and after forming an electroless Ni/Au surface treatment plate layer, respectively. As also shown in respective surface images through the electroless plating type, it can be seen that flat interfaces having slightly different surface shapes from each other but similar levels of surface roughnesses can be obtained.

The reason is that the nickel thickness of a surface treatment layer in a metal exposure part of an outer layer of an electronic device is at least 3 μm, and a surface thereof, as previously known, has a nodule structure (electroless plating), or a crystalline structure, or a flat structure in a micro or smaller sized region.

### SUMMARY OF THE INVENTION

An object of the present invention is to provide a printed circuit board capable of improving wire bonding workability by minimizing defects in wire bonding.

Another object of the present invention is to provide a method for manufacturing the printed circuit board.

According to an exemplary embodiment of the present invention, there is provided a printed circuit board, including: a copper pad surface roughness-treated to have a surface roughness of 0.1 to 1.0 μm pitch period; and an electroless surface treatment plating layer formed on the copper pad.

The electroless surface treatment plating layer may be made of a Ni layer/a Pd layer/an Au layer, and thicknesses thereof may be 0.02 to 1 μm/0.01 to 0.3 μm/0.01 to 0.5 μm, respectively.

The copper pad may be connected to an electronic device by a wire bonding type.

Each of the Ni layer, the Pd layer, and the Au layer of the electroless surface treatment plating layer may have a surface roughness of 0.1 to 1.0 μm pitch period.

According to an exemplary embodiment of the present invention, there is provided a method for manufacturing a printed circuit board, including: roughness-treating a copper pad to have a surface roughness of a predetermined pitch period; and forming an electroless surface treatment plating layer on the roughness-treated copper pad.

The surface roughness of the copper pad may have a pitch period of 0.1 to 1.0 μm.

The roughness-treatment of the copper pad may be performed by chemical treatment or physical treatment.

The electroless surface treatment plating layer may be made of a Ni layer/a Pd layer/an Au layer, and thicknesses thereof may be 0.02 to 1 μm/0.01 to 0.3 μm/0.01 to 0.5 μm, respectively.

Each of the Ni layer, the Pd layer, and the Au layer of the electroless surface treatment plating layer may have a surface roughness of 0.1 to 1.0 μm pitch period.

### BRIEF DESCRIPTION OF THE DRAWINGS

FIGS. 1A and 1B are a cross-sectional view and a plan view of a printed circuit board at the time of connection with a device by using a wire bonding type according to the related aret, respectively;

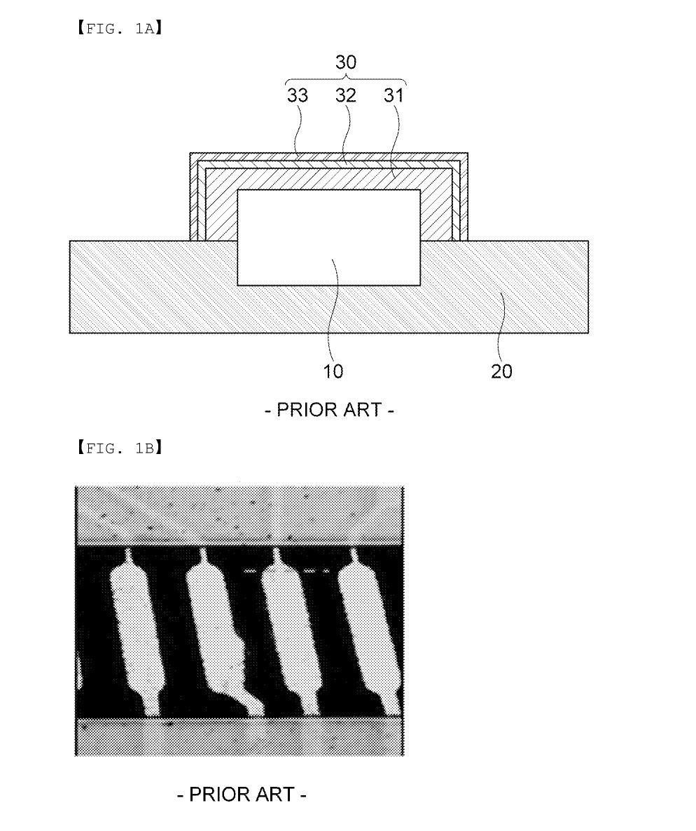

FIGS. 2A to 2C are scanning electron microscope images each showing surface roughness observed during each of the procedures for forming a Ni plating layer by using an electrolytic plating type, and here, FIGS. 2A, 2B, and 2C are surface images before forming a plating layer, after soft etching, and after forming an electrolytic Ni/Au surface treatment plate layer, respectively;

FIGS. 3A to 3C are scanning electron microscope images each showing surface roughness observed during each of the procedures for forming a Ni plating layer by using an electroless plating type, and here, FIGS. 3A, 3B, and 3C are surface images before forming a plating layer, after soft etching, and after forming an electrolytic Ni/Au surface treatment plate layer, respectively;

FIG. 4 is a cross-sectional view of a printed circuit board according to an exemplary embodiment of the present invention, in which a copper pad has a surface roughness; and

FIG. 5 is a scanning electron microscope image showing a surface observed after forming an electroless surface treatment plating layer is formed on the copper pad of FIG. 4.

### DESCRIPTION OF THE PREFERRED EMBODIMENTS

Hereinafter, the present invention will be described in more detail.

Terms used in the present specification are for explaining the embodiments rather than limiting the present invention. Unless explicitly described to the contrary, a singular form may include a plural form in the present specification. The word “comprise” and/or “comprising,” will be understood to imply the inclusion of stated figures, numbers, steps, operations, members, components, and/or groups thereof, but not the exclusion of other figures, numbers, steps, operations, members, components, and/or groups thereof.

The present invention is directed to a printed circuit board capable of improving wire bonding workability by minimizing defects in wire bonding, and a method for manufacturing the printed circuit board.

A printed circuit board of the present invention has a structure including a copper pad roughness-treated to have a surface roughness of 0.1 to 1.0 μm pitch period; and an electroless surface treatment plating layer formed on the copper pad.

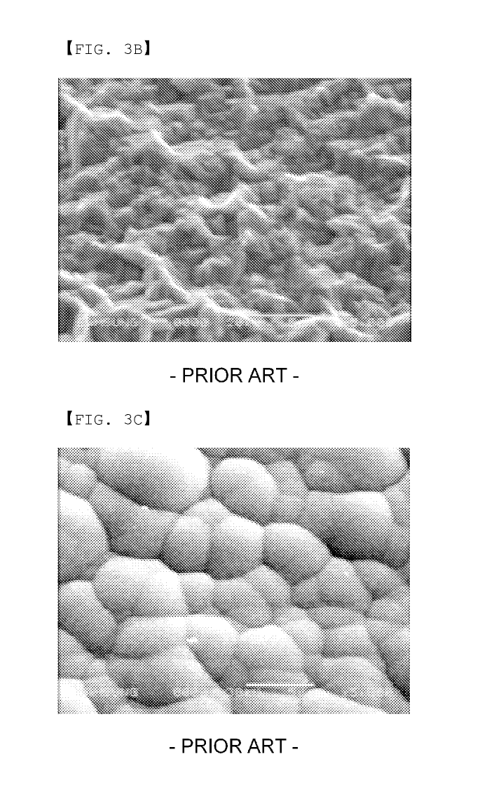

FIG. 4 shows a structure of a printed circuit according to the present invention. Referring to this, a polymer resin layer 120 is formed at a region of a printed circuit board except for a copper pad 110. The polymer resin layer 120 functions as a resist against later plating. Then, an electroless Ni plating layer 131/an electroless Pd plating layer 132/an electroless Au plating layer 133 are formed as a plating layer 130 for protecting the copper layer 110. After the plating layer 130 of Ni/Pd/Au is formed, interconnections between metals are formed by using Au wires.

Here, the copper pad 110 is characterized by being roughness-treated to have a surface roughness of 0.1 to 1.0 μm pitch period. As such, the surface of the copper pad 110 is roughness-treated, thereby increasing surface roughness of the copper pad 110. If the surface roughness of the copper pad is above 1.0 μm pitch period, a surface area cannot be sufficiently increased to a desired size.

An electroless surface treatment plating layer 130 consisting of the electroless Ni plating layer 131/the electroless Pd plating layer 132/the electroless Au plating layer 133 is formed on the copper pad surface, of which a surface is roughness-treated. The electroless Ni plating layer 131/the electroless Pd plating layer 132/the electroless Au plating layer 133 preferably have thicknesses of 0.02 to 1 μm/0.01 to 0.3 μm/0.01 to 0.5 μm, respectively.

When electroless plating is performed after the surface of the copper (Cu) pad 110 is roughness-treated to increase surface roughness thereof, the plating layer can have a surface roughness of a predetermined pitch period according to the surface shape of the copper pad. Therefore, as shown in FIG. 4, it can be seen that the electroless Ni plating layer 131/the electroless Pd plating layer 132/the electroless Au plating layer 133, which constitute the electroless surface treatment plating layer 130, have a surface of a predetermined surface roughness.

Also, since the electroless surface treatment plating layer 130 consisting of the electroless Ni plating layer 131/the electroless Pd plating layer 132/the electroless Au plating layer 133 is formed to be very thin, a surface area thereof can be increased.

The electroless nickel layer 131 preferably has a thickness of 0.02 to 1 μm. If the thickness of the electroless nickel layer 131 is above 1 μm, the electroless nickel layer is remarkably thick, which causes the electroless nickel layer to have a different surface from the Cu layer, which is a layer under the electroless nickel layer. If the thickness of the electroless nickel layer 131 is below 0.02 μm, the electroless nickel layer 131 is remarkably thin, which causes the thickness management to be difficult.

In addition, the electroless nickel layer 131 is formed, and then the electroless palladium (Pd) layer 132 is formed on the electroless nickel layer by plating. The electroless Pd plating layer 132 functions to minimize corrosion of the electroless Ni plating layer due to a substitution reaction during an immersion type Au plating procedure. The electroless palladium layer according to the present invention preferably has a thickness of 0.01 to 0.3 μm. If the thickness of the electroless palladium (Pd) layer is above 0.3 μm, the manufacturing costs are increased.

Finally, the electroless gold (Au) layer 133 is formed on the electroless nickel and palladium layers, by plating. The electroless Au plating layer 133 functions to prevent an oxidation film from being generated during storage, and the electroless gold layer according to the present invention preferably has a thickness of 0.01 to 0.5 μm. If the thickness of the electroless Au plating layer is above 0.5 μm, the manufacturing costs are increased.

As such, the electroless surface treatment layer 130 of Ni/Pd/Au can be preferably applied in connection with an electronic device by using gold (Au) wires by a wire bonding type.

A method for manufacturing the printed circuit board according to the present invention will be described. First, a copper pad is roughness-treated to have a surface roughness of a predetermined pitch period. The roughness-treatment method may be performed through chemical treatment using an etching chemical, or physical treatment by which the copper pad has a surface roughness of the predetermined pitch period, and is not particularly limited. The copper layer is preferably roughness-treated to have a surface roughness of 0.1 to 1.0 μm pitch period.

Next, an electroless surface treatment plating layer is formed on the roughness-treated copper pad.

Any plating solution that can be usually used in the art may be used as nickel, palladium, and gold plating solutions for the electroless surface treatment plating layer according to the present invention, without particular limitation. In addition, a specific plating method follows the general level, and is not particularly limited.

However, in the electroless surface treatment plating layer of the present invention, the electroless nickel, palladium, and gold layers need to have thicknesses in the ranges of 0.02 to 1 μm, 0.01 to 0.3 μm, and 0.01 to 0.5 μm, respectively.

According to the exemplary embodiment of the present invention, the electroless gold plating layer may be formed by a substitution/reduction type. If the electroless gold plating layer is formed by a general substitution type, corrosion holes are formed in the densely formed electroless Ni and Pd plating layers, thereby deteriorating the ability to prevent copper from being diffused. However, when the electroless gold plating layer is formed by a substitution/reduction type, a substitution reaction occurs ultra-instantaneously in the initial stage of the reaction, and thus, the electroless Ni and Pd plating layers are prevented from being damaged, resulting in a gold plating layer having a densely structure.

Hereinafter, examples of the present invention will be described in detail with reference to the accompanying drawings. However, these examples are for illustrating the present invention, and should not be construed to limit the scope of the present invention.

### Example

1) Roughness Treatment of Copper Pad

A copper pad is formed on a substrate subjected to a pretreatment process. Then, the copper pad was roughness-treated to have a surface roughness of about 0.5 μm pitch period, by chemical treatment using, for example, CZ8101 of MEC company.

2) Electroless Ni Plating

The resulting substrate was immersed in an electroless Ni plating solution (TOP NICORON LPH-LF: OKUNO Company product) at 65° C. for 1 minute, followed by washing for 2 minutes, thereby forming an electroless nickel plating layer with a thickness of 0.1 μm on the roughness-treated copper pad.

3) Electroless Pd Plating

The resulting substrate having the electroless Ni plating layer was immersed in an electroless Pd plating solution, XTP (pH 7.2: UYEMURA Company product) at 50° C. for 10 minutes, followed by washing for 2 minutes, thereby forming an electroless palladium plating layer with a thickness of 0.1 μm.

4) Electroless Au Plating

The resulting substrate having the electroless nickel and palladium plating layers was immersed in an electroless gold plating solution (GoBright TSB-72: UYEMURA Company product) at 80° C. for 5 minutes, followed by washing for 2 minutes and drying using a blow dryer for 5 minutes, thereby obtaining a printed circuit board having an electroless gold plating layer with a thickness of 0.1 μm.

5) Wire Bonding

The electroless plating layer of nickel/palladium/gold is connected to an external device by a gold wire.

### Comparative Example 1

A copper pad of which a surface is not roughness-treated was used, and a surface treatment plating layer formed on the copper pad was formed not by an electrolytic plating type but an electroless plating type.

In addition, a printed circuit board having an electrolytic nickel plating layer with a thickness of 3 μm was obtained.

### Comparative Example 2

The same procedure as Example 1 was performed, except that a copper pad of which a surface is not roughness-treated was used and an electroless nickel plating layer with a thickness of 3 μm was formed, thereby obtaining a printed circuit board.

### Experimental Example

Cross-sections of the printed circuit boards obtained from Example and Comparative examples 1 and 2 were observed by using a scanning electron microscope.

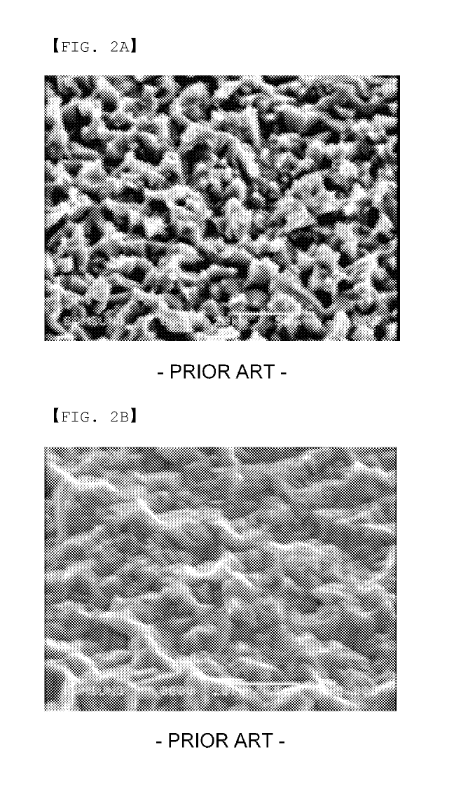

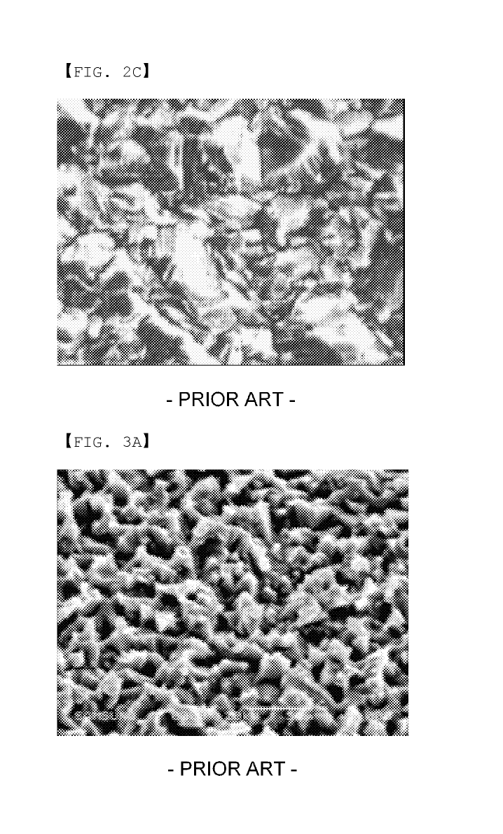

A surface of the printed circuit board including the surface treatment plating layer formed by an electrolytic plating type as shown in FIGS. 2A to 2C and a surface of the printed circuit board including the surface treatment plating layer formed by an electroless plating type as shown in FIGS. 3A to 3C showed flat interfaces, which had no difference in view of surface roughness therebetween. As such, since the plating layer was formed on the surface of the copper layer without particular roughness treatment, the plating layer followed the surface roughness of the nickel layer having a relatively large thickness, and thus, the entire surface of the plating layer was flat.

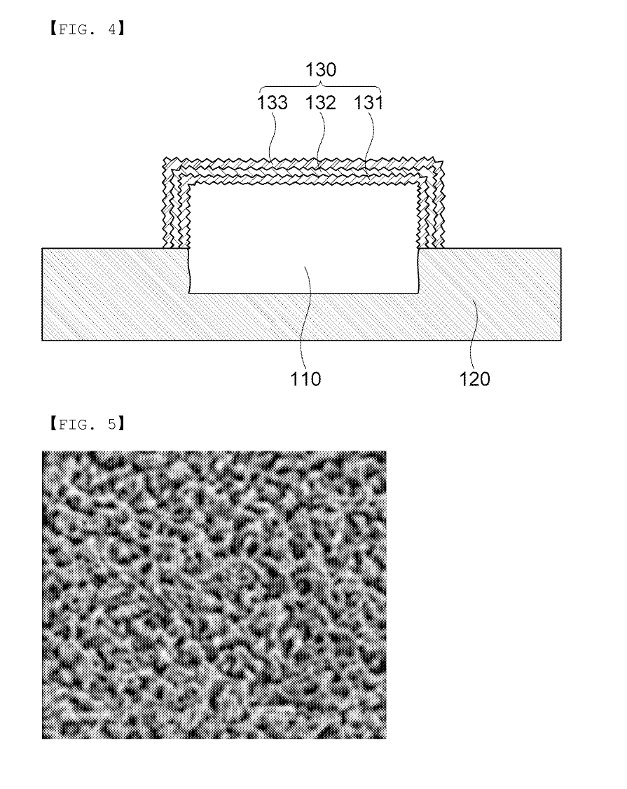

However, from FIG. 5 showing a surface image according to Example 1 of the present invention, it can be seen that surface roughness was increased at the interface. Due to this, when the copper pad has a surface roughness of a predetermined pitch period, the electroless surface treatment plating layer formed on the copper pad also has a surface roughness of the predetermined pitch period, thereby having an effect of widening a surface area. Also, the workability can be improved at the time of a wire bonding process for connection with an external device.

As set forth above, when the copper pad has a surface roughness of a predetermined pitch period, the electroless surface treatment plating layer formed on the copper pad also has a surface roughness of the predetermined pitch period, thereby having an effect of widening a surface area and improving workability at the time of a wire bonding process for connection with an external device.

While the present invention has been shown and described in connection with the embodiments, it will be apparent to those skilled in the art that modifications and variations can be made without departing from the spirit and scope of the invention as defined by the appended claims.

What is claimed is:

1. A printed circuit board, comprising:
a copper pad surface roughness-treated to have a surface roughness of 0.1 to 1.0 μm pitch period; and
an electroless surface treatment plating layer formed on the copper pad.

2. The printed circuit board according to claim 1, wherein the electroless surface treatment plating layer is made of a Ni layer/a Pd layer/an Au layer, and thicknesses thereof are 0.02 to 1 μm/0.01 to 0.3 μm/0.01 to 0.5 μm, respectively.

3. The printed circuit board according to claim 1, wherein the copper pad is connected to an electronic device by a wire bonding type.

4. The printed circuit board according to claim 2, wherein each of the Ni layer, the Pd layer, and the Au layer of the electroless surface treatment plating layer has a surface roughness of 0.1 to 1.0 μm pitch period.

5. A method for manufacturing a printed circuit board, comprising:
roughness-treating a copper pad to have a surface roughness of a predetermined pitch period; and
forming an electroless surface treatment plating layer on the roughness-treated copper pad.

6. The method according to claim 5, wherein the surface roughness of the copper pad has a pitch period of 0.1 to 1.0 μm.

7. The method according to claim 5, wherein the roughness-treatment of the copper pad is performed by chemical treatment or physical treatment.

8. The method according to claim 5, wherein the electroless surface treatment plating layer is made of a Ni layer/a Pd layer/an Au layer, and thicknesses thereof are 0.02 to 1 μm/0.01 to 0.3 μm/0.01 to 0.5 μm, respectively.

9. The method according to claim 5, wherein each of the Ni layer, the Pd layer, and the Au layer of the electroless surface treatment plating layer has a surface roughness of 0.1 to 1.0 μm pitch period.
